(19) United States
(12) Patent Application Publication
(10) Pub. No.: US 2025/0266393 A1
(43) Pub. Date: Aug. 21, 2025

(54) METHOD FOR FABRICATING ELECTRONIC PACKAGE

(71) Applicant: SILICONWARE PRECISION INDUSTRIES CO., LTD., Taichung City (TW)

(72) Inventors: Huan-Shiang LI, Taichung City (TW); Pei-Geng WENG, Taichung City (TW); Yih-Jenn JIANG, Taichung City (TW); Cheng-Kai CHANG, Taichung City (TW); Wei-Son TSAI, Taichung City (TW)

(73) Assignee: SILICONWARE PRECISION INDUSTRIES CO., LTD., Taichung City (TW)

(21) Appl. No.: 18/760,791

(22) Filed: Jul. 1, 2024

(30) Foreign Application Priority Data
Feb. 19, 2024 (TW) 113105812

(51) Int. Cl. H01L 23/00; H01L 23/31; H01L 23/498; H01L 25/00

(52) U.S. Cl. CPC H01L 24/97; H01L 23/3107; H01L 23/49822; H01L 24/20; H01L 25/50; H01L 2224/211; H01L 2224/95001

(57) ABSTRACT

A method for fabricating an electronic package is provided, which mainly provides a first carrier structure on which a plurality of packaging structures are disposed and a cutting path is provided between each of the packaging structures, wherein each of the packaging structures has a circuit structure disposed on the first carrier structure, an electronic component disposed on the circuit structure, an encapsulating layer disposed the circuit structure and encapsulating the electronic component, and a routing structure disposed on the encapsulating layer; a pre-cutting process is performed to remove the routing structure and encapsulating layer above the cutting path to reduce warpage phenomenon, thereby avoiding yield problems in the subsequent process; and a second carrier structure is bonded onto the routing structure and the first carrier structure is removed.

### BACKGROUND

### 1. Technical Field

The present disclosure relates to a semiconductor packaging technology, and more particularly, to a method for fabricating an electronic package.

### 2. Description of Related Art

In response to that the applications of high performance computing (HPC) technology, such as the development of medical technology (such as the development of cancer drugs), or the calculations of automatic sensing and detection of self-driving cars, and so forth, are increasingly important and widespread in today's world, the packaging structures used by the equipment applied in these fields are mostly fan-out package (FOPKG) structures to meet the requirements of multi-chip/high number of circuit layers/large fan-out size/high heat dissipation designs.

The conventional FOPKG structure mainly embeds chips in the cladding layer, then forms redistribution layers (RDL) above, and then disposes functional chips on the redistribution layers. In this way, the functional chips and the chips embedded in the cladding layer can communicate vertically to meet the requirements of high-speed transmission.

However, the fan-out packaging process is performed in a monolithic structure such as a wafer form, at the station of each step in the process, because of the problem of inconsistency of the thermal expansion coefficients produced by the carrier and the dielectric layer, the metal layer above the carrier, and the unevenness of stress caused by the variances of design of the thicknesses and the number of the dielectric layers, metal layers, thereby warpage problems such as some area of the wafer form presents a smiling face (concave center) and some area presents a crying face (convex center) may occur. If the warpage level of the crying face or the smiling face is too high, it makes the wafer form unable to be loaded into the machine, and the fabricating process is not able to proceed.

Therefore, how to overcome the above-mentioned problems of conventional techniques has become an urgent issue to be solved.

### SUMMARY

In view of the aforementioned shortcomings of the prior art, the present disclosure provides a method for fabricating an electronic package, comprising: disposing a plurality of packaging structures that are mutually connected on a first carrier structure, wherein a cutting path is set between any adjacent two of the packaging structures, and each of the packaging structures comprises a circuit structure disposed on the first carrier structure, an electronic component disposed on the circuit structure, an encapsulating layer formed on the circuit structure and encapsulating the electronic component, and a routing structure disposed on the encapsulating layer; performing a pre-cutting process to remove the routing structure and the encapsulating layer above the cutting path; bonding a second carrier structure onto the routing structure; and removing the first carrier structure.

In the aforementioned method for fabricating an electronic package, which further comprises: bonding a plurality of conductive components onto the circuit structure; performing a singulation process to separate each of the packaging structures completely; and removing the second carrier structure.

In the aforementioned method for fabricating an electronic package, the first carrier structure is a monolithic structure of a wafer form.

In the aforementioned method for fabricating an electronic package, each of the packaging structures is a Fan-Out Packaging structure, a Fan-Out Package on Package structure, a Fan-Out Multi-Chip Module or a Fan-out Embedded Bridge Die structure.

In the aforementioned method for fabricating an electronic package, each of the packaging structures further comprises a plurality of conductive pillars disposed on the circuit structure.

In the aforementioned method for fabricating an electronic package, the pre-cutting process removes the routing structure and the encapsulating layer on at least one cutting path by laser cutting, a half cutting process or an etching process, and retains the circuit structure on the at least one cutting path.

In the aforementioned method for fabricating an electronic package, the pre-cutting process is performed on a cutting path where a maximum stress occurs in the fabricating method.

In the aforementioned method for fabricating an electronic package, the cutting path for the pre-cutting process is passing through a center position of the first carrier structure if a warpage of the first carrier structure is in a shape of a smiling face or a crying face. The cutting path for the pre-cutting process is passing through a periphery of the first carrier structure if a warpage of the first carrier structure is in a shape of a saddle.

It can be seen from the above that the method for fabricating an electronic package of the present disclosure mainly records in advance the shape of warpage in the fabricating process of the first carrier structure (such as a monolithic structure of a wafer form) on which a plurality of packaging structures are disposed, and performs the pre-cutting process on the cutting path where the stress is maximum to remove part of material, thereby reducing the warpage phenomenon occurring in the fabricating process and avoiding the problems of yield in the subsequent processes.

### BRIEF DESCRIPTION OF THE DRAWINGS

FIG. 1 to FIG. 4 are schematic cross-sectional views illustrating a method for fabricating an electronic package according to the present disclosure.

FIG. 5A and FIG. 5B are schematic views illustrating stress distributions corresponding to pre-cutting processes in a method for fabricating an electronic package according to the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

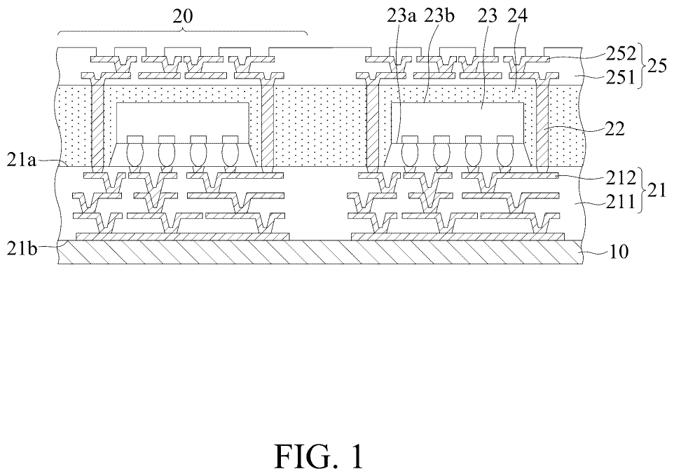

FIG. 1 to FIG. 4 are schematic cross-sectional views illustrating a method for fabricating an electronic package according to the present disclosure.

As shown in the FIG. 1, a first carrier structure 10 is provided, on which a plurality of packaging structures 20 mutually connected are disposed, and a cutting path is set between each of the packaging structures 20 (or between any two adjacent packaging structures 20) in advance. The first carrier structure 10 is a monolithic structure such as a wafer form. The packaging structure 20 may be a Fan-Out Package (FOPKG) structure, for example, a Fan-Out Package on Package (FOPOP) structure, a Fan-Out Multi-Chip Module (FOMCM) or a Fan-out Embedded Bridge Die (FOEB) structure, and so forth.

In an embodiment, the first carrier structure 10 is, for example, a board of semiconductor material (such as silicon or glass) on which a bonding layer of release film or other adhesive film is formed by, for instance, coating. The bonding layer serves as a sacrificial release layer.

The packaging structure 20 comprises a circuit structure 21, a plurality of conductive pillars 22, at least one electronic component 23, an encapsulating layer 24, and a routing structure 25.

The circuit structure 21 is disposed on the first carrier structure 10 and has a first side 21a and a second side 21b opposing the first side 21a, and comprises at least one dielectric layer 211 and a circuit layer 212 bonded to the dielectric layer 211. For example, the material forming the circuit layer 212 may be copper, the material forming the dielectric layer 211 may be Polybenzoxazole (PBO), Polyimide (PI), Prepreg (PP) or other dielectric materials, and so forth, and the circuit layer 212 and the dielectric layer 211 may be form by a redistribution layer (RDL) process. The circuit layer 21 is disposed on the first carrier structure 10 through its second side 21b.

The plurality of conductive pillars 22 are disposed on the first side 21a of the circuit structure 21 to be electrically connected to the circuit layer 212. In an embodiment, the material forming the conductive pillars 22 is a metal material such as copper.

At least one electronic component 23 is disposed on the first side 21a of the circuit structure 21 The electronic component 23 may be an active component, a passive component or a combination thereof, wherein the active component is, for example, a semiconductor chip, and the passive component is, for example, a resistor, a capacitor or an inductor. In an embodiment, the electronic component 23 is a semiconductor chip having an active surface 23a and an inactive surface 23b opposing the active surface 23a.

In an embodiment, a plurality of conductive bumps such as copper pillars, solder balls may be formed on the active surface 23a of the electronic component 23 first, then the electronic component 23 may be bonded to the first side 21a of the circuit structure 21 through the plurality of conductive bumps by a flip-chip way, such that the electronic component 23 is electrically connected to the circuit layer 212. After that, an underfill may formed between the electronic component 23 and the first side 21a of the circuit structure 21 to cover the conductive bumps.

An encapsulating layer 24 is formed on the first side 21a of the circuit structure 21, and a routing structure 25 is formed on the encapsulating layer 24.

In an embodiment, the encapsulating layer 24 encapsulates side surfaces and the inactive surface 23b of the electronic component 23 and side surfaces of the plurality of conductive pillars 22, such that the encapsulating layer 24 is sandwiched between the electronic component 23 and the conductive pillars 22. And, the material forming the encapsulating layer 24 is an insulating material, such as an encapsulant of epoxy.

In an embodiment, a redistribution layer (RDL) process may be used to form the routing structure 25, which comprises a plurality of dielectric layers 251 and a plurality of redistribution layers 252 disposed on the dielectric layers 251 and electrically connected to the plurality of conductive pillars 22. For instance, the material forming the redistribution layers 252 is copper, and the material forming the dielectric layers 251 is Polybenzoxazole (PBO), Polyimide (PI) or Prepreg (PP).

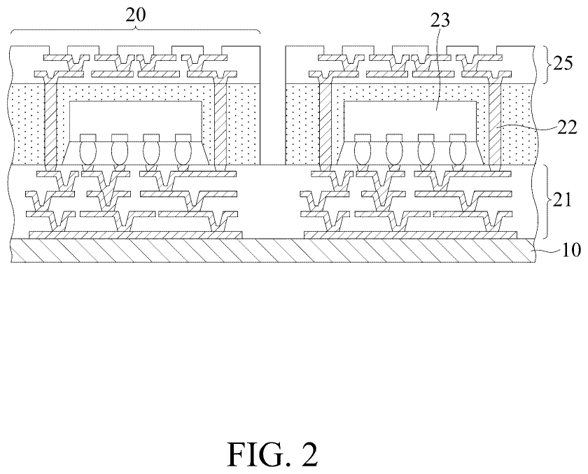

As shown in FIG. 2, the routing structure 25 and the encapsulating layer 24 (and even part of the circuit structure 21) above the cutting paths between the plurality of packaging structures 20 are removed by means of a pre-cutting process (e.g., laser cutting, a half-cutting process or an etching process, etc.), but at least part of the circuit structure 21 above the cutting paths is still retained, and each of the packaging structures 20 has not been separated completely.

In a practical operation, the shape of the warpage of each packaging structure 20 presented can first be recorded station by station in the fabricating process for the first carrier structure 10 (e.g., the monolithic structure of a wafer form) which is provided with the plurality of the packaging structures 20 and is not pre-cut, and then the pre-cutting process (e.g., laser cutting, half-cutting process or etching process, etc.) is performed for a part of the cutting paths where a severer warpage occurs (not necessary for all the cutting paths) to remove the routing structure 25 and the encapsulating layer 24 above the cutting paths, thereby releasing stress and avoiding serious warping problems.

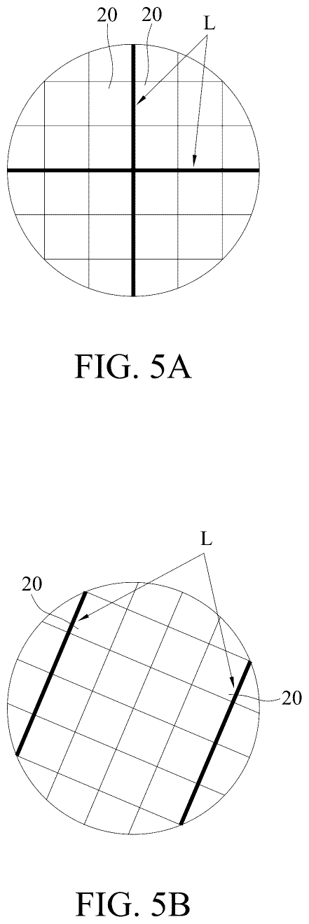

In an embodiment, as shown in FIG. 5A, if the warpage of the monolithic structure of a wafer form is in the shape of a smiling face or of a crying face, then the maximum stress will occur at the center position of the first carrier structure, therefore the cutting path L (at least one cutting path) of pre-cutting will pass through the center of the monolithic structure of the wafer form. In another embodiment, as shown in FIG. 5B, if the warpage is in the shape of a saddle, then the maximum stress will occur at the positions on two sides of the first carrier structure, therefore the cutting path L of pre-cutting will close to the periphery of the monolithic structure of the wafer form.

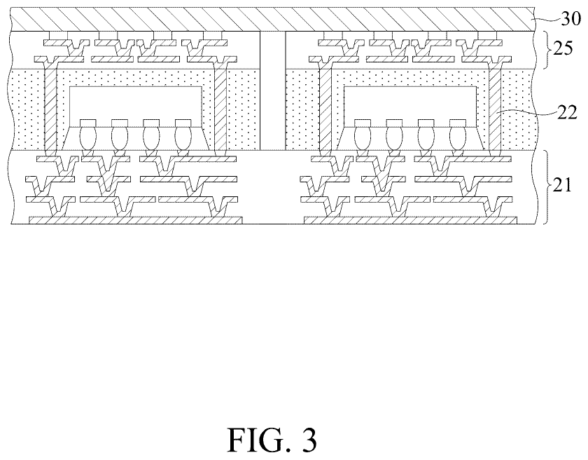

As shown in FIG. 3, a second carrier structure 30 is bonded onto the routing structure 25, then the first carrier structure 10 is removed to expose the circuit structure 21.

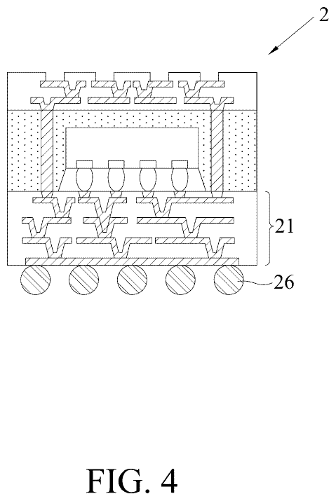

As shown in FIG. 4, a plurality of conductive components 26 such as solder bumps or solder balls (the specification of them is C4 type) are bonded onto the circuit structure 21. A singulation process is performed (to separate each of the packaging structures 20 completely) and the second carrier structure 30 is removed, such that a plurality of electronic packages 2 are obtained.

Therefore, in a method for fabricating an electronic package of the present disclosure, it mainly records in advance the shape of warpage of the first carrier structure (e.g., a monolithic structure of a wafer form) having a plurality of packaging structure disposed thereon in the fabricating process, and performs the pre-cutting process on the cutting path where the maximum stress occurs to remove part of material, thereby reducing the warpage phenomenon avoiding the problems of yield in the subsequent processes. In addition, the aforementioned structure does not require the addition of new development processes and materials or the purchase of machines, the existing materials and the original processes and machines can be used to solve the industry's existing technical problems, so there is no large additional costs.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A method for fabricating an electronic package, comprising:
disposing a plurality of packaging structures that are mutually connected on a first carrier structure, wherein a cutting path is set between any adjacent two of the packaging structures, and each of the packaging structures comprises a circuit structure disposed on the first carrier structure, an electronic component disposed on the circuit structure, an encapsulating layer formed on the circuit structure and encapsulating the electronic component, and a routing structure disposed on the encapsulating layer;
performing a pre-cutting process to remove the routing structure and the encapsulating layer above the cutting path;
bonding a second carrier structure onto the routing structure; and
removing the first carrier structure.

2. The method of claim 1, further comprising: bonding a plurality of conductive components onto the circuit structure.

3. The method of claim 2, further comprising: performing a singulation process to separate each of the packaging structures completely.

4. The method of claim 3, further comprising: removing the second carrier structure.

5. The method of claim 1, wherein the first carrier structure is a monolithic structure of a wafer form.

6. The method of claim 1, wherein each of the packaging structures is a Fan-Out Packaging structure, a Fan-Out Package on Package (FOPOP) structure, a Fan-Out Multi-Chip Module (FOMCM) or a Fan-out Embedded Bridge Die (FOEB) structure.

7. The method of claim 1, wherein each of the packaging structures further comprises a plurality of conductive pillars disposed on the circuit structure.

8. The method of claim 1, wherein the pre-cutting process removes the routing structure and the encapsulating layer on at least one cutting path by laser cutting, a half cutting process or an etching process, and retains the circuit structure on the at least one cutting path.

9. The method of claim 1, wherein the pre-cutting process is performed on a cutting path where a maximum stress occurs in the method.

10. The method of claim 9, wherein the cutting path for the pre-cutting process is passing through a center position of the first carrier structure if a warpage of the first carrier structure is in a shape of a smiling face or a crying face.

11. The method of claim 9, wherein the cutting path for the pre-cutting process is passing through a periphery of the first carrier structure if a warpage of the first carrier structure is in a shape of a saddle.
